(19) United States
(12) Patent Application Publication
(10) Pub. No.: US 2025/0103776 A1
(43) Pub. Date: Mar. 27, 2025

(54) OPTIMIZING DESIGN PARAMETERS USING A SIMULATION NEURAL NETWORK

(71) Applicant: DeepMind Technologies Limited, London (GB)

(72) Inventors: Kelsey Rebecca Allen, London (GB); Tatiana Lopez Guevara, Edinburgh (GB); Kimberly Stachenfeld, London (GB); Jessica Blake Chandler Hamrick, London (GB); Alvaro Sanchez, London (GB); Peter William Battaglia, London (GB); Tobias Pfaff, London (GB)

(21) Appl. No.: 18/832,787

(22) PCT Filed: Jan. 30, 2023
(86) PCT No.: PCT/EP2023/052177

§ 371 Date: Jul. 24, 2024

Related U.S. Application Data
(60) Provisional application No. 63/304,306, filed on Jan. 28, 2022.

(51) Int. Cl. G06F 30/27; G06F 30/15; G06N 3/042; G06N 3/084

(52) U.S. Cl. CPC G06F 30/27; G06F 30/15; G06N 3/042; G06N 3/084

(57) ABSTRACT

Methods, systems, and apparatus, including computer programs encoded on a computer storage medium, for optimizing a set of design parameters. In one aspect, a method includes: obtaining a respective initial value for each design parameter, and iteratively optimizing current values of the design parameters over a sequence of optimization iterations. The method further includes, each optimization iteration: generating a representation of an initial state of an environment using the current values of the design parameters, processing an input including the representation of the initial state of the environment using a simulation neural network to generate an output that defines a simulation of the state of the environment over a sequence of one or more time steps, determining a reward, determining gradients of the reward with respect to the current values of the design parameters, and updating the current values of the design parameters using the gradients.

### CROSS-REFERENCE TO RELATED APPLICATIONS

This application claims the benefit of the filing date of U.S. Provisional Patent Application Ser. No. 63/304,306 for “OPTIMIZING DESIGN PARAMETERS USING A SIMULATION NEURAL NETWORK,” which was filed on Jan. 28, 2022, and which is incorporated here by reference in its entirety.

### BACKGROUND

This specification relates to processing data using machine learning models.

Machine learning models receive an input and generate an output, e.g., a predicted output, based on the received input. Some machine learning models are parametric models and generate the output based on the received input and on values of the parameters of the model.

Some machine learning models are deep models that employ multiple layers of models to generate an output for a received input. For example, a deep neural network is a deep machine learning model that includes an output layer and one or more hidden layers that each apply a non-linear transformation to a received input to generate an output.

### SUMMARY

This specification generally describes an optimization system implemented as computer programs on one or more computers in one or more locations. The optimization system can generate a design, e.g., of an object, by iteratively adjusting a set of design parameters that collectively define the design to optimize a “reward,” e.g., that measures a quality of the design defined by the design parameters.

According to a first aspect, there is provided a method for optimizing a set of design parameters, the method including: obtaining a respective initial value for each design parameter in the set of design parameters, and iteratively optimizing current values of the design parameters over a sequence of optimization iterations. The method further includes, at each optimization iteration: generating a representation of an initial state of an environment using the current values of the design parameters, processing an input including the representation of the initial state of the environment using a simulation neural network, in accordance with values of a set of simulation neural network parameters, to generate an output that defines a simulation of the state of the environment over a sequence of one or more time steps, determining a reward based on the simulation of the state of the environment, where the reward measures a quality of a design defined by the current values of the design parameters, determining gradients of the reward with respect to the current values of the design parameters, and updating the current values of the design parameters using the gradients.

In some implementations, determining gradients of the reward with respect to the current values of the design parameters includes: backpropagating gradients through the set of simulation neural network parameters and into the set of design parameters.

In some implementations, updating the current values of the design parameters using the gradients includes: updating the current values of the design parameters using the gradients in accordance with a gradient descent optimization rule.

In some implementations, the set of design parameters represent a design of a physical object.

In some implementations, at each optimization iteration, the environment includes the object having the design represented by the current values of the set of design parameters.

In some implementations, the object is a wing of an aircraft.

In some implementations, determining the reward based on the simulation of the state of the environment includes: determining one or more aerodynamic features of the object based on the simulation of the state of the environment, and determining the reward based on the aerodynamic features of the object.

In some implementations, at each optimization iteration, the representation of the initial state of the environment includes data representing a graph including multiple nodes.

In some implementations, each node in the graph represents a particle in the environment or a vertex in a mesh.

In some implementations, the simulation neural network has a graph neural network architecture.

In some implementations, generating the output that defines the simulation of the state of the environment over the sequence of one or more time steps includes, for each time step: obtaining a representation of the state of the environment at the time step, and processing the representation of the state of the environment at the time step using the simulation neural network to generate an output that defines a representation of the state of the environment at a next time step.

In some implementations, the values of the set of simulation neural network parameters are static during the optimization of the set of design parameters.

In some implementations, the method further includes, after a last optimization iteration, outputting the current values of the design parameters.

In some implementations, the set of design parameters comprises at least 500 design parameters.

In some implementations, the simulation neural network is one simulation neural network in an ensemble of multiple simulations neural networks, and the method includes, at each optimization iteration: for each simulation neural network in the ensemble of simulation neural networks: processing the input including the representation of the initial state of the environment using the simulation neural network to generate an output that defines a respective simulation of the state of the environment over multiple time steps, determining a respective reward based on the respective simulation of the state of the environment, and determining respective gradients of the respective reward with respect to the current values of the design parameters, and updating the current values of the design parameters using the respective gradients determined using each simulation neural network in the ensemble of simulation neural networks.

In some implementations, each simulation neural network in the ensemble of simulation neural networks has been trained on a different set of training data.

In some implementations, each simulation neural network in the ensemble of simulation neural networks has a respective set of simulation neural network parameters that are initialized to respective random values prior to being trained.

In some implementations, updating the current values of the design parameters using the respective gradients determined using each simulation neural network in the ensemble of simulation neural networks includes: averaging the gradients determined using each simulation neural network in the ensemble of simulation neural networks, and updating the current values of the design parameters using the average of the gradients.

According to a second aspect, there is provided a system including: one or more computers, and one or more storage devices communicatively coupled to the one or more computers, where the one or more storage devices store instructions that, when executed by the one or more computers, cause the one or more computers to perform the operations of the respective method of any preceding aspect.

According to a third aspect, there are provided one or more non-transitory computer storage media storing instructions that when executed by one or more computers cause the one or more computers to perform the operations of the respective method of any preceding aspect.

The subject matter described in this specification can be implemented in particular embodiments so as to realize one or more of the following advantages.

At each of multiple optimization iterations, the optimization system can compute a reward achieved by current values of design parameters using a simulation neural network, e.g., that simulates the physics of an environment, and determine gradients of the reward with respect to the design parameters. The optimization system can then use the gradients to adjust the current values of the design parameters to increase the reward, e.g., by a gradient descent technique. The optimization system can thus exploit the differentiability of the simulation neural network to directly optimize the quality of a design by iteratively adjusting the values of the design parameters using gradients of a reward.

Optimizing the quality of a design using gradients of a reward computed by way of a simulation neural network can enable the optimization system to generate high quality designs significantly faster and using fewer computational resources (e.g., memory and computing power) than conventional systems. For example, some conventional systems optimize designs using optimization techniques (e.g., evolutionary techniques) that rely on making large numbers of random adjustments to the values of design parameters. These optimization techniques are computationally intensive and may even fail to converge in high-dimensional design spaces, e.g., with hundreds or thousands of design parameters. In contrast, the optimization system described in this specification adjusts the design parameters using gradients of the reward, thus directly optimizing the reward and causing the design parameters to rapidly converge on high quality designs. Moreover, conventional simulation models can be slow and computationally intensive, e.g., as a result of performing complex iterative optimizations to model the physics of an environment each time a new simulation is generated. In contrast, the optimization system described in this specification uses a simulation neural network that, once trained, can directly generate an accurate simulation by the operation of its parameters.

The optimization system can optionally generate a design by optimizing a reward using an ensemble of multiple simulation neural networks, i.e., rather than a single simulation neural network. Simulation neural networks in the ensemble can have different parameter values, e.g., as a result of being trained on different sets of training data. At each optimization iteration, the optimization system can compute gradients of the reward using each simulation neural network in the ensemble, and then apply a combination (e.g., average) of the gradients to adjust the design parameters. Adjusting the design parameters using combined gradients generated using an ensemble of simulation neural networks can enable the design parameters to smoothly converge on a high quality design over fewer optimization iterations than might otherwise be required, thus improving the efficiency of the optimization.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example design optimization system.

FIG. 2 illustrates an example process for optimizing design parameters.

FIG. 3 is a block diagram of an example ensemble of simulation neural networks.

FIG. 4 is a flow diagram of an example process for optimizing design parameters.

FIG. 5 illustrates example experimental results achieved using the design optimization system.

FIG. 6 illustrates another example of experimental results achieved using the design optimization system.

FIG. 7 illustrates another example of experimental results achieved using the design optimization system.

Like reference numbers and designations in the various drawings indicate like elements.

### DETAILED DESCRIPTION

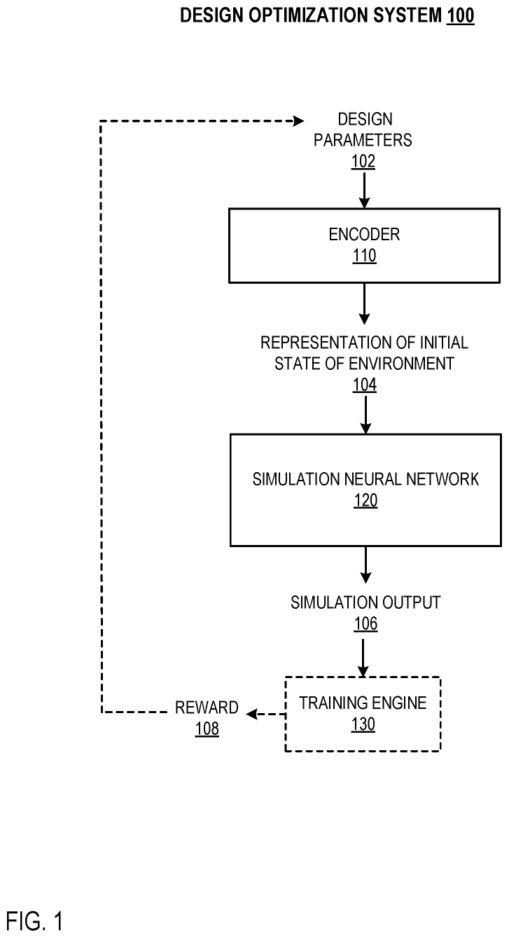

FIG. 1 is a block diagram of an example design optimization system 100 that can optimize a set of design parameters 102. The design optimization system 100 is an example of a system implemented as computer programs on one or more computers in one or more locations in which the systems, components, and techniques described below are implemented.

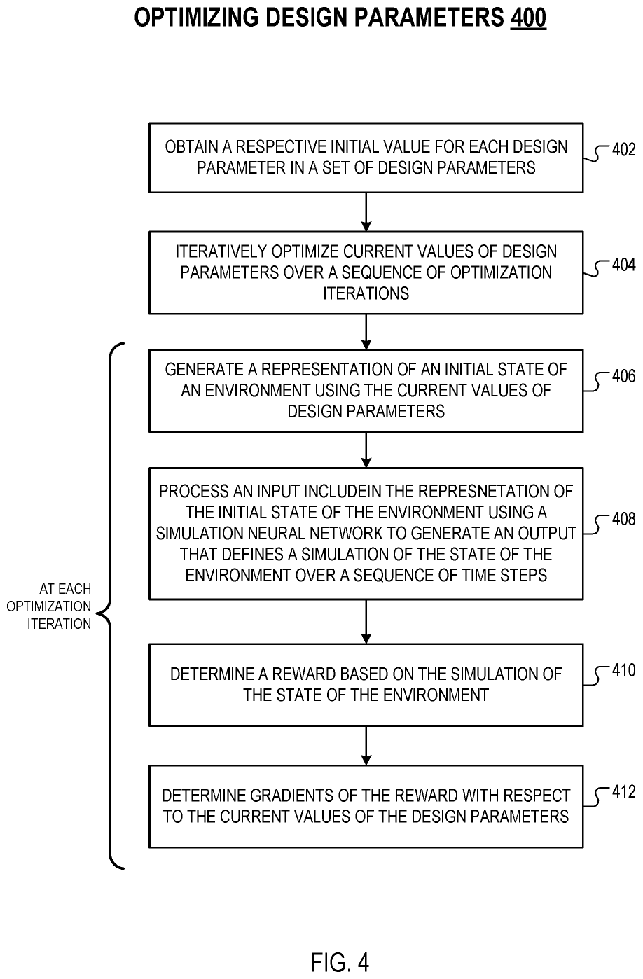

The set of design parameters 102 can collectively define a design of an entity. The entity can be any appropriate entity and the set of design parameters 102 can define any appropriate aspect of the design of the entity. In one example, the entity can be, e.g., a physical object, and the set of design parameters 102 can define, e.g., a shape, a configuration, and/or a structure of the physical object. As a particular example, the entity can be, e.g., a wing of an aircraft, and the set of design parameters 102 can define the shape of the wing. This example is illustrated in FIG. 4. In another example, the entity can be, e.g., an electrical process, a mechanical process, or a chemical process, and the set of design parameters 102 can define, e.g., a design of one or more of the process steps. The set of design parameters 102 can generally include any appropriate number of parameters, e.g., 5 parameters, 10 parameters, 100 parameters, 500 parameters, 1,000 parameters, or any other appropriate number of design parameters. Examples of design parameters are described in more detail next.

In some cases, the design parameters can define, e.g., a shape of an object, e.g., all or part of a vehicle, e.g., a car, a truck, an aircraft, a watercraft, a rocket, etc. In particular examples, the design parameters can define the shape of a wing of an aircraft or the shape of a hull of a watercraft. The design parameters can define the shape of an object, e.g., by defining a respective position of each control point in a set of control points that parametrize the shape of the object, or by defining the vertices and edges of a mesh representing the shape of the object.

In some cases, the design parameters can define, e.g., a structure of an object, e.g., of a vehicle, a bridge, or a building. In particular examples, the design parameters can define the structure of the chassis or frame of a vehicle, or the structure of supports within a bridge or building. The design parameters can define the structure of an object, e.g., by representing the positions, orientations, thicknesses, and connectivity of rods, beams, struts, and ties defining the structure of the object.

In some cases, the design parameters can define, e.g., a composition of a material, e.g., an alloy. In particular examples, the design parameters can define the composition of a material, e.g., by defining, for each of multiple possible constituent materials, a fraction of the material that is represented by the constituent material.

In some implementations, the design parameters can define a design of a process, e.g., a chemical process, an electrical process, a mechanical process, or a combination thereof.

For example, the design parameters can define a design of a chemical process, e.g., defining when and how various chemicals should be combined in a chemical process. For example, the design parameters can define the speed of a mixer that agitates the contents of a vat, and for each chemical in a set of chemicals, when the chemical should be added to the vat and in what amount.

As another example, the design parameters can define a design of a mechanical process, e.g., defining, for each fan in an environment (e.g., a mine): (i) a rotational speed of the blades of the fan, and (ii) an orientation of the fan. The design optimization system 100 can be configured to obtain a respective initial value for each design parameter in the set of design parameters 102 that collectively define a design of the entity, and generate the design of the entity by iteratively adjusting the set of design parameters 102. The design optimization system 100 can obtain initial values of design parameters 102 in any appropriate manner, e.g., the initial values can be provided by a user of the system 100 through an API made available by the system 100, or the initial values can be randomly sampled from an appropriate probability distribution, e.g., a Normal distribution.

In some implementations, the set of design parameters 102 can define the design of the entity with reference to an environment, e.g., the environment can include an object having the design represented by the set of design parameters 102. An “environment” can generally refer to any appropriate type of environment, e.g., a physical environment, such as a fluid, a rigid solid, a field, a deformable material, any other appropriate type of environment, or a combination thereof. In some cases, data defining an initial state of the environment can be provided as an input to the design optimization system 100, e.g., by a user of the system 100. The system 100 can optimize the design parameters 102 by performing a simulation of the environment, as described in more detail below. A “simulation” of the environment can include a respective simulated state of the environment at each time step in a sequence of time steps. Generally, a state of the environment can be defined in any appropriate manner. In some cases, the state of the environment can be defined, e.g., by a collection of particles, or a mesh, as described in more detail below.

In one example, a state of the environment can be represented by, e.g., a collection of particles, where each particle is associated with a set of particle features. Particle features associated with a particle can be defined by, e.g., a vector that specifies a spatial location (e.g., spatial coordinates) of the particle and, optionally, various physical properties associated with that particle including, e.g., a mass, a velocity, an acceleration, etc. The environment can be represented using any appropriate number of particles, e.g., 100, 1000, 10000, 100000, or any other appropriate number of particles.

In another example, a state of the environment can be represented by a mesh that can, e.g., span the whole of the environment, or represent respective surfaces of one or more entities (e.g., objects) in the environment. Generally, a “mesh” refers to a data structure that includes multiple mesh nodes and mesh edges, where each mesh edge connects a pair of mesh nodes. In some cases, the mesh can represent environments that include continuous fields, e.g., a spatial region associated with a physical quality (e.g., velocity, pressure, etc.) that varies continuously across the region. The mesh can define an irregular (unstructured) grid that specifies a tessellation of a geometric domain (e.g., a surface, or space) into smaller elements (e.g., cells, or zones) having a particular shape, e.g., a triangular shape, or a tetrahedral shape. Each mesh node can be associated with a respective spatial location in the environment.

Similarly to particle-based representations described above, each mesh node in a mesh can be associated with current mesh node features that characterize a current state of the environment at a position in the environment corresponding to the mesh node. For example, each mesh node can represent fluid viscosity, fluid density, or any other appropriate physical aspect, at a position in the environment that corresponds to the mesh node. For the mesh-based representation of the environment, the set of design parameters 102 can define the design of the entity with reference to the mesh, e.g., mesh nodes and mesh edges. In some cases, the design parameters 102 can define the shape of the object by, e.g., defining the mesh nodes and mesh edges of the mesh that represents the shape of the object. The above examples are provided for illustrative purposes only. It should be understood that the set of design parameters 102 can define the design of the entity with reference to any type of environment, and a state of the environment can generally be defined in any appropriate manner. In some cases, a state of the environment that includes the entity (e.g., defined by the set of design parameters 102) can be defined in terms of both particles and a mesh. For example, the environment can be defined by a collection of particles, while a surface of the entity (e.g., an object in the environment) can be defined through mesh nodes and mesh edges. Other configurations are also possible.

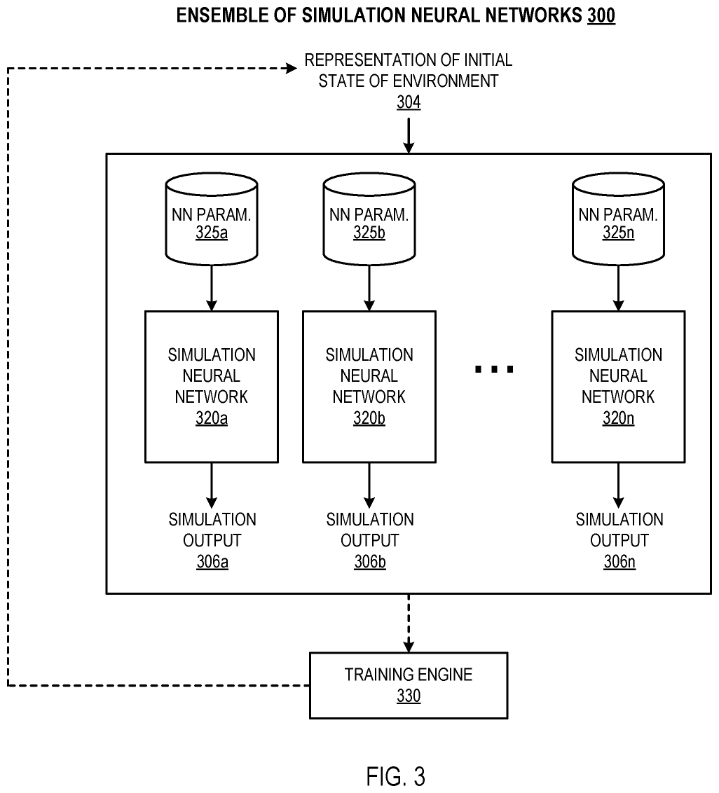

The design optimization system 100 can iteratively optimize the set of design parameters 102 by using: (i) an encoder 110, (ii) a simulation neural network 120, and (iii) a training engine 130, each of which is described in more detail next. In some cases, the design optimization system 100 can include an ensemble of multiple simulation neural networks. This is described in more detail below with reference to FIG. 3.

At each optimization iteration, the encoder 110 can be configured to process current values of the set of design parameters 102 to generate a representation of an initial state of the environment 104. As described above, the initial state of the environment can be defined by a collection of particles, a mesh, or a combination thereof. The initial state of the environment (e.g., defined by a collection of particles, a mesh, or a combination thereof) can be represented by a graph. A “graph” refers to a data structure that includes a set of graph nodes and a set of graph edges, such that each edge connects a respective pair of nodes. The encoder 110 can be configured to process the current values of the set of design parameters 102 and, optionally, data defining the initial state of the environment, to generate a representation of the initial state of the environment 104 as the graph.

If the initial state of the environment is defined by a collection of particles, the encoder 110 can assign a node in the graph to each of the particles in the collection of particles defining the initial state of the environment, and instantiate edges between pairs of nodes in the graph. In order to determine which pairs of nodes in the graph should be connected by an edge, the encoder 110 can identify each pair of particles in the initial state of the environment that have respective positions (e.g., as defined by their respective spatial coordinates) which are separated by less than a threshold distance, and instantiate an edge between such pairs of particles. The search for neighboring nodes can be performed via any appropriate search algorithm, e.g., a kd-tree algorithm. The operation of the encoder 110 with respect to the mesh-based representations of the initial state of the environment is described in more detail below.

The encoder 110 can include a node embedding sub-network and an edge embedding sub-network. In addition to assigning nodes to each of the particles, and instantiating edges between pairs of nodes corresponding to the particles, the encoder 110 can use the node embedding sub-network to generate a respective node embedding for each node in the graph. Specifically, the node embedding sub-network 111 of the encoder 110 can process particle features associated with the particle represented by the node and the current values of the set of design parameters 102 to generate a respective node embedding for each node in the graph.

The encoder 110 can also generate an edge embedding for each edge in the graph. Generally, an edge embedding for an edge connecting a pair of nodes in the graph can represent pairwise properties of the corresponding particles represented by the pair of nodes. For each edge in the graph, the edge embedding sub-network of the encoder 110 can process features associated with the pair of nodes in the graph connected by the edge, and the current values of the design parameters 102, and generate a respective current edge embedding of the edge. Specifically, the edge embedding sub-network can generate an embedding for each edge connecting a pair of nodes in the graph based on e.g., respective positions of the particles corresponding to the nodes connected by the edge, a difference between the respective positions of the particles corresponding to the nodes connected by the edge, a magnitude of the difference between the respective positions of the particles corresponding to the nodes connected by the edge, or a combination thereof. In some implementations, instead of determining the pairwise properties of particles and generating an embedding on that basis, the current edge embeddings for each edge in the graph can be predetermined.

As described above, the design optimization system 100 can iteratively optimize the set of design parameters 102. At each optimization time step, the system 100 can generate the representation of the initial state of the environment 104 as the graph by using the encoder 110, e.g., as described above. After generating the graph that represents the initial state of the environment 104, at each optimization time step, the design optimization system 100 can provide the representation of the initial state of the environment 104 to the simulation neural network 120. At each optimization time step, the simulation neural network 120 can be configured to process an input including the representation of the initial state of the environment 104 to generate a simulation output 106 that defines a simulation of the state of the environment over a sequence of internal iterations (simulation steps). In other words, for each optimization time step, the simulation output 106 can include multiple simulation states, where each simulation state represents a simulated state of the environment at a respective internal iteration of the simulation neural network 120.

The simulation neural network 120 can generate the simulation output 106 by updating the representation of the initial state of the environment 104 as the graph over multiple internal iterations to generate an updated graph for the optimization time step.

“Updating” a graph refers to, at each internal iteration, performing a step of message-passing (e.g., a step of propagation of information) between the nodes and edges included in the graph by, e.g., updating the node and/or edge embeddings for some or all nodes and edges in the graph based on node and/or edge embeddings of neighboring nodes in the graph. In other words, at each internal iteration, the simulation neural network 120 maps an input graph onto an output graph, where the output graph may have the same structure as the input graph (e.g., the same nodes and edges) but different node and edge embeddings. The number of internal iterations can be, e.g., 1, 10, 100, 1000, 100,000, or any other appropriate number, and can be a predetermined hyper-parameter of the simulation neural network 120.

More specifically, the simulation neural network 120 can include a node updating sub-network and an edge updating sub-network. At each internal iteration, the node updating sub-network can process the current node embedding for a node included in the graph, and the respective current edge embedding for each edge that is connected to the node in the graph, to generate an updated node embedding for the node. Further, at each internal iteration, the edge updating sub-network can process the current edge embedding for the edge and the respective current node embedding for each node connected by the edge to generate an updated edge embedding for the edge. The final internal iteration of the simulation neural network 120 generates data defining the final updated graph for the optimization time step.

As described above, the design optimization system 100 can further include a training engine 130. The training engine 130 can be configured to process the simulation output 106 defining the simulation of the state of the environment over a sequence of one or more simulation time steps, and update the current values of the design parameters 102. At each optimization time step, the training engine 130 can update the current values of the design parameters 102 by determining a reward 108. The reward 108 can be, e.g., any appropriate numerical value, e.g., a scalar value. Generally, the reward 108 can characterize, e.g., a quality of the design of the entity achieved by the current values of the design parameters 102. In other words, the reward 108 can represent, e.g., how well the design of the entity defined by the current values of the design parameters 102 serves a particular purpose or fulfils a particular function. As a particular example, if the entity is a wing of an aircraft, then the reward 108 can characterize, e.g., one or more aerodynamic features of the wing.

At each optimization time step, the training engine 130 can be configured to process the simulation output 106 to determine the reward 108 for the optimization time step. In some cases, the training engine 130 can be configured to process, e.g., data defining the final updated graph for the optimization time step generated by the simulation neural network 120. Specifically, the training engine 130 can process a respective node embedding for one or more nodes in the updated graph (e.g., updated node embeddings) to generate a respective feature corresponding to each of the one or more nodes in the updated graph. The feature can be, e.g., any appropriate feature of the particle represented by the node, e.g., a position of the particle, a velocity of the particle, an acceleration of the particle, or any other appropriate feature of the particle represented by the node. As a particular example, the feature can be, e.g., a final position of the particle represented by the node. In this case, the training engine 130 can determine the reward 108 using, e.g., a Gaussian likelihood of the final particle positions. However, this example is provided for illustrative purposes only. Generally, the training engine 130 can determine the reward 108 in any appropriate manner. Examples of different rewards are described in more detail below.

At each optimization time step, the training engine 130 can use the reward 108 to update the current values of the design parameters 102. For example, the training engine 130 can determine gradients of the reward 108 with respect to the current values of the design parameters 102, e.g., using backpropagation techniques. As a particular example, the training engine 130 can backpropagate gradients of the reward through a set of simulation neural network parameters and into the set of design parameters 120. In some cases, the set of simulation neural network parameters can be held static during the optimization of the set of design parameters 102. The training engine 130 can update the current values of the design parameters 102 using the gradients in accordance with a gradient descent optimization rule. The gradient descent optimization rule can be based on any appropriate gradient descent optimization method, e.g., Adam or RMSprop.

As described above, the set of design parameters 102 can be optimized with respect to a state of the environment that is defined by a collection of particles. However, some environments can be more appropriately defined as a mesh, e.g., a mesh that spans the environment and/or a mesh that defines, by means of the set of design parameters 102, the design of one or more entities (e.g., objects) in the environment. For example, environments that include, e.g., continuous fields, deformable materials and/or complex structures, can be represented by a mesh. A “continuous field” generally refers to, e.g., a spatial region associated with a physical quality (e.g., velocity, pressure, etc.) that varies continuously across the region. For example, each spatial location in a velocity field can have a particular value of velocity associated with it. To optimize the set of design parameters 102 that are defined with respect to mesh-based environments, the design optimization system 100 can generate a representation of an initial state of the mesh-based environment 104 as a graph, update the graph over a number of internal iterations to generate the simulation output 106, and use the simulation output 106 to update current values of the set of design parameters 102. Various aspects of this process are described in more detail next.

Generally, a “mesh” refers to a data structure that includes multiple mesh nodes and mesh edges, where each mesh edge connects a pair of mesh nodes. Similarly to particle-based representations described above, each mesh node in a mesh can be associated with current mesh node features that characterize a current state of the environment at a position in the environment corresponding to the mesh node. For example, in implementations that involve simulations of environments with continuous fields, such as, e.g., in a fluid dynamics or aerodynamics simulations, each mesh node can represent fluid viscosity, fluid density, or any other appropriate physical aspect, at a position in the environment that corresponds to the mesh node.

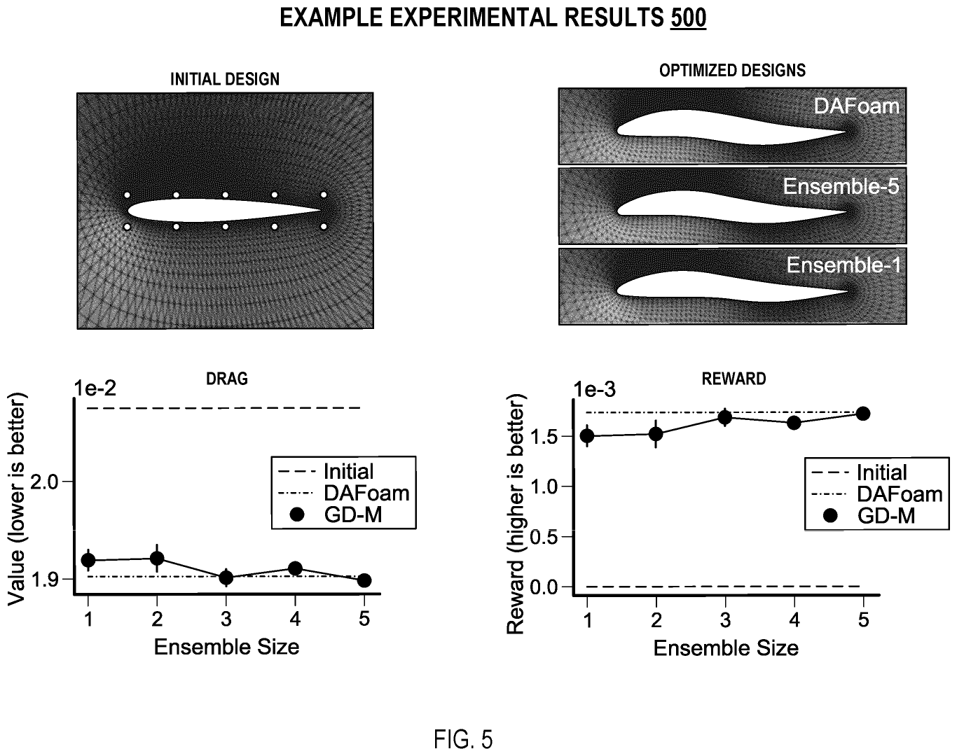

As described above, in some cases, the environment can include the entity (e.g., the object) the design of which is defined by the set of design parameters 102. As a particular example, in some cases, the object can be, e.g., a wing of an aircraft, the environment can include a fluid (e.g., air), and the design parameters 102 can define the mesh nodes and mesh edges of a mesh defining the shape of the wing. This example is illustrated in FIG. 5.

As another example, in structural mechanics simulations, each mesh node can define a point on an object in the environment and can be associated with object-specific mesh node features that characterize the point on the object, e.g., the position of a respective point on the object, the pressure at the point, the tension at the point, and any other appropriate physical aspect. Furthermore, each mesh node can additionally be associated with mesh node features including one or more of: a fluid density, a fluid viscosity, a pressure, or a tension, at a position in the environment corresponding to the mesh node. Generally, mesh representations are not limited to the aforementioned physical systems and entities, and other types of physical systems and entities can also be defined by a mesh.

At each optimization time step, the encoder 110 can process the set of design parameters 102, and optionally, data defining the initial state of the environment as a mesh, and generate the representation of the initial state of the environment 104, e.g., as a graph. Specifically, at each optimization time step, the encoder 110 can assign a graph node to each mesh node included in the mesh. Further, for each pair of mesh nodes that are connected by a mesh edge, the encoder 110 can instantiate an edge between the corresponding pair of nodes in the graph. In addition to generating the graph, the encoder 110 can process mesh node and mesh edge features to generate node and edge embeddings associated with the nodes and edges in the graph, respectively, e.g., in a similar way as described above for particle-based environments. Accordingly, for each optimization time step, the encoder 110 can process the mesh, and the set of design parameters 102, to generate the representation of the initial state of the environment 104 as the graph with associated graph node embeddings and graph edge embeddings.

At each optimization time step, the simulation neural network 120 can update the representation of the initial state of the environment 104 as the graph over multiple internal iterations to generate the final updated graph for the optimization time step, e.g., in a similar way as described above. Specifically, at each internal iteration, the node updating sub-network of the simulation neural network can process an input that includes (i) the current node embedding for the node, and (ii) the respective current edge embedding for each edge that is connected to the node, to generate an updated node embedding for the node. Similarly, at each internal iteration, the edge updating sub-network can be configured to process an input that includes: (i) the current edge embedding for the edge, and (ii) the respective current node embedding for each node connected by the edge, to generate an updated edge embedding for the edge. After updating the graph, the simulation neural network 120 can generate the simulation output 106 that defines a simulation of the state of the environment over a sequence of one or more simulation time steps.

As described above for particle-based environments, at each optimization time step, the training engine 130 can process the simulation output 106 to determine the reward 108 that measures a quality of the design defined by the current values of the design parameters 102 for the optimization time step. For example, the training engine 130 can process a respective node embedding for one or more nodes in the updated graph (e.g., updated node embeddings) to generate a respective feature corresponding to each of the one or more nodes in the updated graph. As a particular example, the environment can include a fluid, e.g., air, and the entity in the environment can be a wing of an aircraft. In such cases, the training engine 130 can process a respective node embedding for one or more graph nodes in the updated graph, and a respective edge embedding for one or more graph edges in the graph, to determine one or more aerodynamic features of the wing in the environment represented by the mesh. For example, the training engine 130 can determine, e.g., a pressure field and an effective Reynolds stress at each mesh node represented by graph node in the updated graph.

Based on the aerodynamic features of the wing, the training engine 130 can determine the reward 108 for the optimization time step. As a particular example, the training engine 130 can determine the reward as follows:

$${f}_{R} := - {C}_{D} - {γ}_{L} {‖ {C}_{L} - {C}_{L 0} ‖}^{2} - {γ}_{A} a ( {φ}_{ctrl} ) \qquad ( 1 )$$

where f_{R} is the reward, C_{D} is a drag coefficient, C_{L0} is an initial lift coefficient, C_{L} is a final lift coefficient, γ_{L} and γ_{A} are constants, a is the wing area, and φ_{ctrl} is a position of each control point in a set of control points that parametrizes the shape of the wing. The training engine 130 can determine the final lift coefficient C_{L} and the drag coefficient C_{D} from the mesh node features decoded form the final graph such as, e.g., the pressure field and the effective Reynolds stress at each mesh node represented by graph node in the final graph (e.g., the graph generated by the final internal iteration of the simulation neural network 120).

After determining the reward 108, the training engine 130 can use the reward to update the current values of the design parameters 102, e.g., in a similar way as described above for environments represented as a collection of particles. As described above, in some cases, the values of the set of simulation neural network parameters can be held static during the optimization of the set of design parameters 102. However, in some cases, the training engine 130 can train the set of simulation neural network parameters on a set of training data over multiple training iterations. This process is described in more detail below with reference to FIG. 3.

The encoder 110, the simulation neural network 120, and the training engine 130 can have any appropriate neural network architectures that enables them to perform their described function. For example, they can have any appropriate neural network layers (e.g., convolutional layers, fully connected layers, recurrent layers, attention layers, etc.) in any appropriate numbers (e.g., 2 layers, 5 layers, or 10 layers) and connected in any appropriate configuration (e.g., as a linear sequence of layers). The simulation neural network 120 can be a graph neural network, e.g., can include one or more graph neural network layers.

After optimizing the set of design parameters 102 over multiple optimization time steps, e.g., as described above, the system 100 can use the design parameters 102 to generate the design of the entity (e.g., object). For example, after the last optimization time step, the system 100 can output the current values of the design parameters 102, which can be used to generate the design of the physical (e.g., real-world) entity. Generally, the optimization system 100 is broadly applicable, in particular, the optimization system 100 can be applied to iteratively adjust any appropriate set of design parameters to optimize any appropriate reward. The design parameters can define the design of any appropriate entity with reference to any appropriate environment, and the simulation neural network can simulate any appropriate aspects of the environment. For illustrative purposes, a few example applications of the optimization system 100 are described next.

In some implementations, the design parameters can define a design of one or more physical objects. A few example applications of the optimization system to designing physical objects are described next.

In some cases, the design parameters can define, e.g., a shape of an object, e.g., all or part of a vehicle, e.g., a car, a truck, an aircraft, a watercraft, a rocket, etc. In particular examples, the design parameters can define the shape of a wing of an aircraft or the shape of a hull of a watercraft. The design parameters can define the shape of an object, e.g., by defining a respective position of each control point in a set of control points that parametrize the shape of the object, or by defining the vertices and edges of a mesh representing the shape of the object.

The optimization system can iteratively adjust design parameters representing an object shape to optimize a reward representing, e.g., a measure of one or more aerodynamic features of the object (e.g., a drag coefficient or a lift coefficient of the object), or a measure of physical stress or force exerted on the object under specified environment conditions (e.g., the maximum stress exerted on any part of the object).

The optimization system can optimize a reward defining a quality of an object shape using a simulation neural network that simulates, e.g., fluid (e.g., air) dynamics in an environment. For example, the simulation neural network can simulate a stress field or a pressure field in an environment, e.g., that defines a respective stress or pressure at each position in a grid or mesh spanning the environment.

In some cases, the design parameters can define, e.g., a structure of an object, e.g., of a vehicle, a bridge, or a building. In particular examples, the design parameters can define the structure of the chassis or frame of a vehicle, or the structure of supports within a bridge or building. The design parameters can define the structure of an object, e.g., by representing the positions, orientations, thicknesses, and connectivity of rods, beams, struts, and ties defining the structure of the object.

The optimization system can iteratively adjust design parameters representing an object structure to optimize a reward representing, e.g., the behavior of the structure under a mechanical load, e.g., a maximum force, stress, or pressure on any part of the structure under the mechanical load.

The optimization system can optimize a reward defining a quality of an object structure using a simulation neural network that simulates, e.g., structural mechanics in an environment. For example, the simulation neural network can simulate a force, stress, or pressure field, e.g., that defines a respective force, stress, or pressure at each position in a grid or mesh spanning the structure.

In some cases, the design parameters can define, e.g., a composition of a material, e.g., an alloy. In particular examples, the design parameters can define the composition of a material, e.g., by defining, for each of multiple possible constituent materials, a fraction of the material that is represented by the constituent material.

The optimization system can iteratively adjust design parameters representing a composition of a material to optimize a reward characterizing, e.g., corrosion of the material over time, or behavior of an object made of the material under a mechanical load.

The optimization system can iteratively adjust design parameters representing a composition of a material using a simulation neural network that simulates, e.g.: changes in the chemical composition of the material over time resulting from specified environmental conditions; or a force, stress, or pressure field representing force, stress, or pressure at each position in a grid or mesh spanning an object made of the material.

In some implementations, the design parameters can define a design of a process, e.g., a chemical process, an electrical process, a mechanical process, or a combination thereof. A few example applications of the optimization system to designing a process are described next.

In some cases, the design parameters can define a design of a chemical process, e.g., defining when and how various chemicals should be combined in a chemical process. For example, the design parameters can define the speed of a mixer that agitates the contents of a vat, and for each chemical in a set of chemicals, when the chemical should be added to the vat and in what amount.

The optimization system can iteratively adjust design parameters representing a design of a chemical process to optimize a reward measuring, e.g., a yield of the chemical process, e.g., an amount of a desired end product that is produced as a result of the chemical process; or a quality (e.g., purity) of the end product.

The optimization system can optimize a reward defining a quality of the chemical process using a simulation neural network that simulates, e.g., chemical dynamics within an environment. For example, the simulation neural network can simulate a concentration field in an environment, e.g., that defines a respective concentration of each of one or more chemicals at each position in a grid or mesh spanning the environment.

In some cases, the design parameters can define a design of a mechanical process, e.g., defining, for each fan in an environment (e.g., a mine): (i) a rotational speed of the blades of the fan, and (ii) an orientation of the fan.

In this example, the optimization system can iteratively adjust the design parameters to optimize a reward characterizing, e.g., a distribution and concentration of one or more gasses (e.g., oxygen) in the environment, e.g., as a result of the operation of the fans. The optimization system can optimize the reward using a simulation neural network that simulates airflow in the environment and concentration of gasses in the environment. For example, the simulation neural network can simulate a flow field in the environment, e.g., that defines a respective direction of airflow, strength of airflow, and concentration of gasses at each position in a grid or mesh spanning the environment.

Optimized design parameters generated by the optimization system can be used for any of a variety of purposes. For example, if the design parameters represent a shape or structure of a physical object (e.g., an aircraft wing), then the optimized design parameters can be provided for use in manufacturing an object having the design defined by the design parameters. The object can be manufactured using any appropriate manufacturing process, e.g., a machining process or an additive manufacturing process. In particular, the optimization system can implement an appropriate manufacturing process to manufacture an object having the design defined by the design parameters. As another example, if the design parameters define the design of a process, e.g., a chemical process or a mechanical process, then the optimized design parameters can be provided for use in implementing a process having the design defined by the design parameters. In particular, the optimization system can implement a process having the design defined by the design parameters.

When the design parameters define the shape or configuration of a physical object the method can include making a physical object to a design specified by the optimized design parameters.

The reward may be a scalar value and may define one or more characteristics to be optimized by the design parameters. A characteristic to be minimized may be specified e.g. by a negative reward. Optionally the reward may include a constraint objective. The constraint objective may define one or more constraints that the design should aim to satisfy. For example a constraint objective may define a target or minimum or maximum value for a physical characteristic e.g. defining a physical size, or shape, or strength, or weight, of the object or of part of the object, or a parameter relating to manufacturability e.g. a bend radius. Where the reward is a scalar value to be maximized the constraint objective may define a negative scalar value that is added to the reward. Where the constraint objective defines a target value for a characteristic it may comprise a measure of a difference between a value for the characteristic and the target value.

In some further examples, the physical environment may be a fluid flow environment, e.g. a liquid flow environment. The reward may then characterize fluid flow over the object. Merely as some additional examples, in a fluid flow environment the physical object may comprise: a pipe or other liquid conduit; the reward may characterize fluid flow through the pipe or conduit, or surface coverage of the pipe or conduit by the fluid e.g. for optimizing these, e.g. to optimize cooling or lubrication using the pipe or conduit. A fan, turbine, impeller, pump or pump part; the reward may then characterize fluid flow through the fan, turbine, impeller, pump or pump part, e.g. for maximizing fluid flow or for minimizing resistance to fluid flow. An engine or motor, e.g. an internal combustion engine, gas turbine, or electric motor; the reward may then characterize a fluid flow through the engine or part of the engine e.g. an inlet or exhaust or coolant path, for optimizing the fluid flow. A nozzle, a mechanical device to entrain particles in a fluid flow such as an inhaler or a device to entrain solid or liquid particles in a spray; the reward may then characterize a liquid spray from the nozzle or a quantity or dispersion of solid or liquid particles entrained in the spray, for optimizing these. A medical device used to transport a fluid, or over or over which a fluid flows (such as a stent); the reward may then characterize the fluid flow e.g. for maximizing fluid flow or for minimizing resistance to fluid flow. A fluidized bed; the reward may then characterize fluidization within the bed.

The simulation neural network may have a graph neural network architecture to process a graph comprising nodes and edges. For example a fluid, i.e. a fluid flow environment, may be represented as particles, where the features of the particles are represented by nodes as node embeddings, and features of interactions between the particles by edges, as edge embeddings. The node embeddings may define static features such as a type of the fluid, and boundaries (“boundary particles”), and dynamics features such as particle position and velocity (present or/and historical) updated e.g. by predicting particle acceleration. Then the dynamics features, e.g. fluid motion, for a next time step may be determined by predicting particle motion. As one example the details of sections 3 and 4.2 of Sanchez-Gonzalez et al. arXiv: 2002.09405 are incorporated by reference.

In another example where the simulation neural network has a graph neural network architecture, the physical environment may be represented as a mesh that spans the environment, with values of one or more fields such as a velocity, momentum, density or pressure field, or any other physical field, defined at nodes of the mesh. Features of the nodes of the mesh may be represented by node embeddings of nodes of the graph and features of interactions between nodes of the mesh by edge embeddings of edges of the graph. The mesh node features may have static features e.g. a feature that indicates whether or not the node is part of the physical object being designed, or part of a boundary of the physical object being designed, or a boundary such as a wall; or whether the node is a fluid node i.e. a node for part of a fluid in which the physical object is embedded. The mesh node features may also include dynamics features representing changing aspects of the environment e.g. representing a rate of change of one or more of the fields. Then the field(s) for a next time step may be determined by predicting updated dynamics features for the nodes. The reward characterizing the simulation of the state of the environment may be determined from the field(s), e.g. to characterize a fluid flow in terms of an effect of the field(s) on the object such as a force, pressure, or stress on the object e.g. integrated over part of all of a surface of the object. As one example the details of sections 3.1-3.3 of Pfaff et al. arXiv:2010.03409 are incorporated by reference.

In some implementations the simulation neural network is trained using a ground truth simulator. In some implementations the simulation neural network is trained using data from a simulated environment that is different to the environment used for designing the object. That is, the training data may exclude the specific environment used for designing the object, or one or more specific shapes or configurations of the object, e.g. ones that are explored by the method when the design parameters are optimized, or ones that have physical features less than a threshold size. In this way the simulation neural network can learn to produce more accurate simulations than are defined by the ground truth simulator since “classical” simulators can fail in complex environments.

Increasing a length of the sequence of time steps over which the state of the environment is simulated can result in higher quality designs, but long rollouts can have stability issues. In some implementations the simulation neural network is trained using training data from a simulated environment and noise is added to the training data e.g. of a similar magnitude to the errors in the training output, using the output from the ground truth simulator without the noise as the training target. This allows the simulation neural network to learn to correct noise and improves stability, facilitating longer rollouts and higher quality designs.

An example process for optimizing the set of design parameters is described in more detail below.

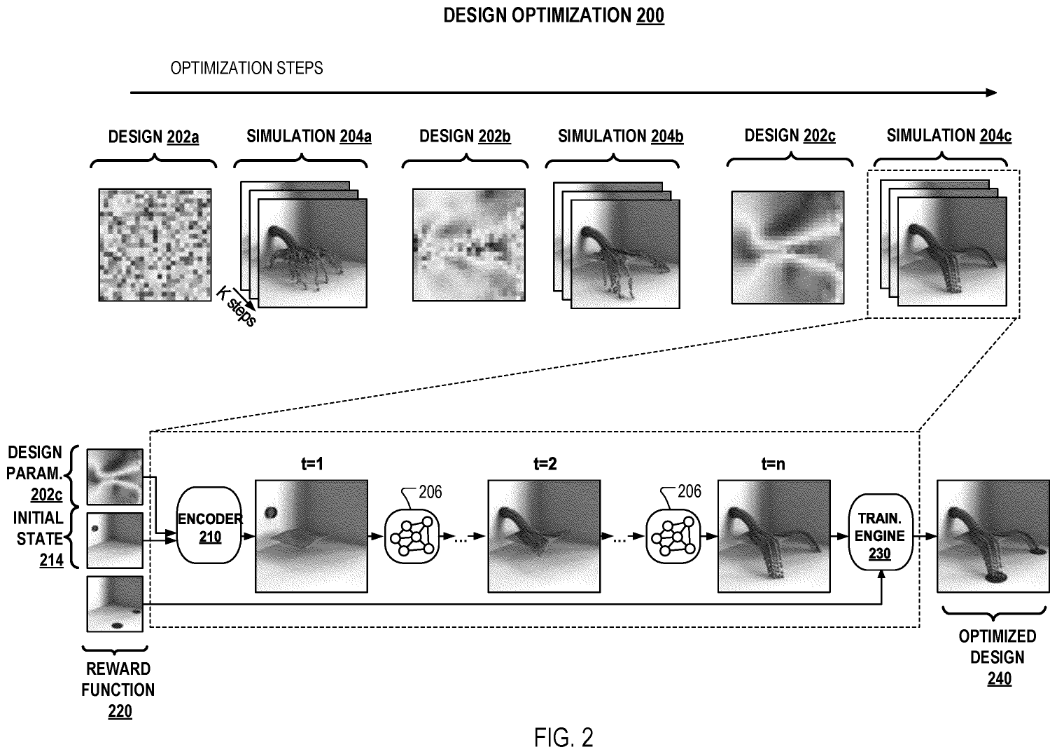

FIG. 2 illustrates an example process for optimizing design parameters over multiple optimization iterations that can be performed by a design optimization system (e.g., the design optimization system 100 in FIG. 1).

As described above with reference to FIG. 1, the system can optimize the set of design parameters over multiple optimization time steps, e.g., three optimization time steps are shown in FIG. 2. At a first optimization time step, the system can process current values of the set of design parameters 202a and use a simulation neural network to generate a first simulation output 204a that defines a simulation of the state of the environment over a sequence of one or more time steps (e.g., k time steps, as shown in FIG. 2). The system can use the first simulation output 204a to update current values of the set of design parameters 202a to determine updated values of the set of design parameters 202b. At the second optimization time step, the system can process the updated values of the set of design parameters 202b and use the simulation neural network to generate a second simulation output 204b.

The system can use the second simulation output 204b to once again update the set of design parameters 202b to determine new updated values of the set of design parameters 202c. At the last optimization time step, the system can process the new updated values of the set of design parameters 202c and use the simulation neural network to generate a third simulation output 204c. The system can use the third simulation output 204c to update the set of design parameters for the last time. After the final optimization time step, the system can, e.g., output the values of the set of design parameters generated at the last optimization time step.

An exploded view of the last optimization iteration is shown at the bottom of FIG. 2. At the last optimization iteration, the system obtains the set of design parameters 202c determined at the previous optimization iteration, and data defining an initial state of the environment 214. In some cases, the system can additionally receive data defining a reward function 220, e.g., as shown above by equation (1). An encoder 210 can generate a representation of the initial state of the environment as a graph 206. The simulation neural network can update the graph 206 over multiple internal iterations (e.g., t=1, t=2 . . . t=n) and generate a simulation output that defines a simulation of the state of the environment over a sequence of n time steps. At the final optimization iteration, the training engine 230 can use the simulation output to update the current values of the set of design parameters 202c to determine final values of the set of design parameters. In some cases, the system can use the final values of the set of design parameters to generate an optimized design of the entity 240.

An example ensemble of multiple simulation neural networks is described in more detail next.

FIG. 3 is a block diagram of an example ensemble of simulation neural networks 300 that can be included in a design optimization system (e.g., the design optimization system 100 in FIG. 1). The ensemble of simulation neural networks 300 is an example of a system implemented as computer programs on one or more computers in one or more locations in which the systems, components, and techniques described below are implemented.

As described above with reference to FIG. 1, the design optimization system can be configured to iteratively optimize a set of design parameters that define a design of an entity (e.g., an object). For example, the system can be configured to process the set of design parameters to generate a representation of an initial state of an environment. The system can use a simulation neural network to process an input that includes the representation of the initial state of the environment, in accordance with values of a set of simulation neural network parameters, to generate an output that defines a simulation of the state of the environment over a sequence of one or more time steps. Then, the system can use the simulation output to determine a reward and use the reward to update current values of the design parameters.

As illustrated in FIG. 3, in some cases, instead of having a single simulation neural network, the design optimization system can include an ensemble of multiple simulation neural networks, e.g., a first simulation neural network 320a, a second simulation neural network 320b, and an n^{th} simulation neural network 320n. Generally the ensemble 300 can include any appropriate number of simulation neural networks 320, e.g., 2 neural networks, 5 neural networks, 10 neural networks, 50 neural networks, or any other appropriate number of simulation neural networks.

At each optimization iteration, each neural network 320 can be configured to process an input that includes the representation of the initial state of the environment 340 to generate a respective simulation output 306, e.g., an output that defines a respective simulation of the state of the environment over multiple time steps, e.g., in a similar way as described above with reference to FIG. 1. As illustrated in FIG. 3, the first simulation neural network 320a can process the representation 304 to generate a first simulation output 306a, the second simulation neural network 320b can process the representation 304 to generate a second simulation output 306b, and the n^{th} simulation neural network 320n can process the representation 304 to generate an n^{th} simulation output 306n.

At each optimization iteration, for each of the simulation neural networks 320, a training engine 330 can determine a respective reward based on the respective simulation of the state of the environment. Then, the training engine 330 can determine respective gradients of the respective reward with respect to the current values of the design parameters, e.g., in a similar way as described above with reference to FIG. 1, but for each of the multiple simulation neural networks 320 in the ensemble 300. At each optimization iteration, after determining the respective gradients, the training engine 330 can update the current values of the design parameters using the respective gradients determined using each simulation neural network 320 in the ensemble of simulation neural networks 300. For example, the training engine 330 can average the gradients determined using each simulation neural network 320 in the ensemble 300, and then update the current values of the design parameters using the average of the gradients. Adjusting the design parameters using combined gradients generated using the ensemble of simulation neural networks 300 can enable the design parameters to smoothly converge on a high quality design over fewer optimization iterations than might otherwise be required, thus improving the efficiency of the optimization.

In some implementations, the simulation neural networks 320 in the ensemble 300 can have different parameter values, e.g., as a result of being trained on different sets of training data. For example, the first simulation neural network 320a can have a first set of parameters 325a, the second simulation neural network 320b can have a second set of parameters 325b, and the nth simulation neural network 320n can have an nth set of parameters 325n. In some cases, the training engine 330 can pre-train each of the simulation neural networks 320 in the ensemble 300 before the system uses the simulation neural networks 320 for optimizing the set of design parameters. After pre-training each of the simulation neural networks 320 in the ensemble, the parameter values of each of the simulation neural networks 320 can be held static while the system uses the ensemble 300 to optimize the set of design parameters. An example process for training a single simulation neural network 320 in the ensemble 300 is described in more detail next.

The training engine 330 can train the simulation neural network 320 by using, e.g., supervised learning techniques on a set of training data. The training data can include a set of training examples, where each training example can specify: (i) a training input that can be processed by the simulation neural network 320, and (ii) a target output that should be generated by the simulation neural network 320 by processing the training input. The training data can be generated by, e.g., a ground-truth simulator (e.g., a physics engine), or in any other appropriate manner.

At each training iteration, the training engine 330 can sample a batch of one or more training examples from the training data and provide them to the simulation neural network 320 that can process the training inputs specified in the training examples to generate corresponding outputs. The training engine can evaluate an objective function that measures a similarity between: (i) the target outputs specified by the training examples, and (ii) the outputs generated by the simulation neural network 320, e.g., a cross-entropy or squared-error objective function.

The training engine 330 can determine gradients of the objective function, e.g., using backpropagation techniques, and can update the parameter values of the simulation neural network 320 using the gradients, e.g., using any appropriate gradient descent optimization algorithm, e.g., Adam. The training engine 330 can determine a performance measure of the simulation neural network 320 on a set of validation data that is not used during training of the simulation neural network 320. In mesh-based implementations, the training engine 330 can train the simulation neural network 320 in a similar way as described above, but the training inputs can include mesh node features, instead of particle features.

Furthermore, in mesh-based implementations, the training data can be generated by using, e.g., a ground-truth simulator that is specific to a particular type of physical environment. The simulation neural network 320 can therefore be trained by using different types of training data, where each training data is generated by a different ground-truth simulator and is specific to a particular type of the physical environment. The training engine 330 can use the process described above to train each of the simulation neural networks 320 in the ensemble but on a different set of training data. After training, the system can use the ensemble of simulation neural networks 300 to optimize the set of design parameters that define the design of an entity.

An example process for optimizing the set of design parameters is described in more detail next.

FIG. 4 is a flow diagram of an example process 400 for optimizing a set of design parameters. For convenience, the process 400 is described as being performed by a system of one or more computers located in one or more locations. For example, an optimization system, e.g., the optimization system 100 of FIG. 1, appropriately programmed in accordance with this specification, can perform the process 400.

The system obtains a respective initial value for each design parameter in the set of design parameters (402). The set of design parameters can represent a design of a physical object, e.g., a wing of an aircraft. In some cases, the set of design parameters can include at least 500 design parameters.

The system iteratively optimizes current values of the design parameters over a sequence of optimization iterations (404). In some cases, at each optimization iteration, the environment can include the object having the design represented by the current values of the set of design parameters.

At each optimization iteration, the system generates a representation of an initial state of an environment using the current values of the design parameters (406). In some cases, the representation of the initial state of the environment can include data representing a graph including multiple nodes. Each node in the graph can represent a particle in the environment or a vertex in a mesh.

The system processes an input including the representation of the initial state of the environment using a simulation neural network, in accordance with values of a set of simulation neural network parameters, to generate an output that defines a simulation of the state of the environment over a sequence of one or more time steps (408). The simulation neural network can have a graph neural network architecture. The system can generate the output by obtaining, for each time step, a representation of the state of the environment at the time step. Then, for each time step, the system can process the representation of the state of the environment at the time step using the simulation neural network to generate an output that defines a representation of the state of the environment at a next time step. In some cases, the values of the set of simulation neural network parameters can be static during the optimization of the set of design parameters.

The system determines a reward based on the simulation of the state of the environment, where the reward measures a quality of a design defined by the current values of the design parameters (410). For example, the system can determine one or more aerodynamic features of the object based on the simulation of the state of the environment. Then, the system determines the reward based on the aerodynamic features of the object.

The system determines gradients of the reward with respect to the current values of the design parameters (412). For example, the system can backpropagate gradients through the set of simulation neural network parameters and into the set of design parameters.

The system updates the current values of the design parameters using the gradients. For example, the system can update the current values of the design parameters using the gradients in accordance with a gradient descent optimization rule.

In some implementations, after a last optimization iteration, the system can output the current values of the design parameters.

In some implementations, the simulation neural network can be one simulation neural network in an ensemble of multiple simulations neural networks. In such cases, at each optimization iteration, and for each simulation neural network, the system can process the input including the representation of the initial state of the environment using the simulation neural network to generate an output that defines a respective simulation of the state of the environment over multiple time steps. For each simulation neural network, the system can determine a respective reward based on the respective simulation of the state of the environment. For each simulation neural network, the system can determine respective gradients of the respective reward with respect to the current values of the design parameters. Then, the system can update the current values of the design parameters using the respective gradients determined using each simulation neural network in the ensemble of simulation neural networks. For example, the system can average the gradients determined using each simulation neural network in the ensemble of simulation neural networks. Then, the system can update the current values of the design parameters using the average of the gradients.

In some cases, each simulation neural network in the ensemble of simulation neural networks can have a respective set of simulation neural network parameters that are initialized to respective random values prior to being trained. In some cases, each simulation neural network in the ensemble of simulation neural networks has been trained on a different set of training data.

Example experimental results achieved using the design optimization system are described in more detail below.

FIG. 5 illustrates example experimental results 500 achieved using the design optimization system described in this specification. As illustrated in FIG. 5, the set of design parameters define a shape of a wing, e.g., by defining a respective position of each control point in a set of ten control points that parametrize the shape of the wing. The mesh defining the environment includes 4158 mesh nodes. FIG. 5 compares results achieved by the optimization system using an ensemble of simulation neural networks including one neural network, and an ensemble of simulation neural networks having five neural networks. It can be appreciated that the design optimization system described in this specification is able to match the performance of the ground-truth simulator using the ensemble having five simulation neural networks, while being significantly less computationally intensive than the ground-truth simulator.

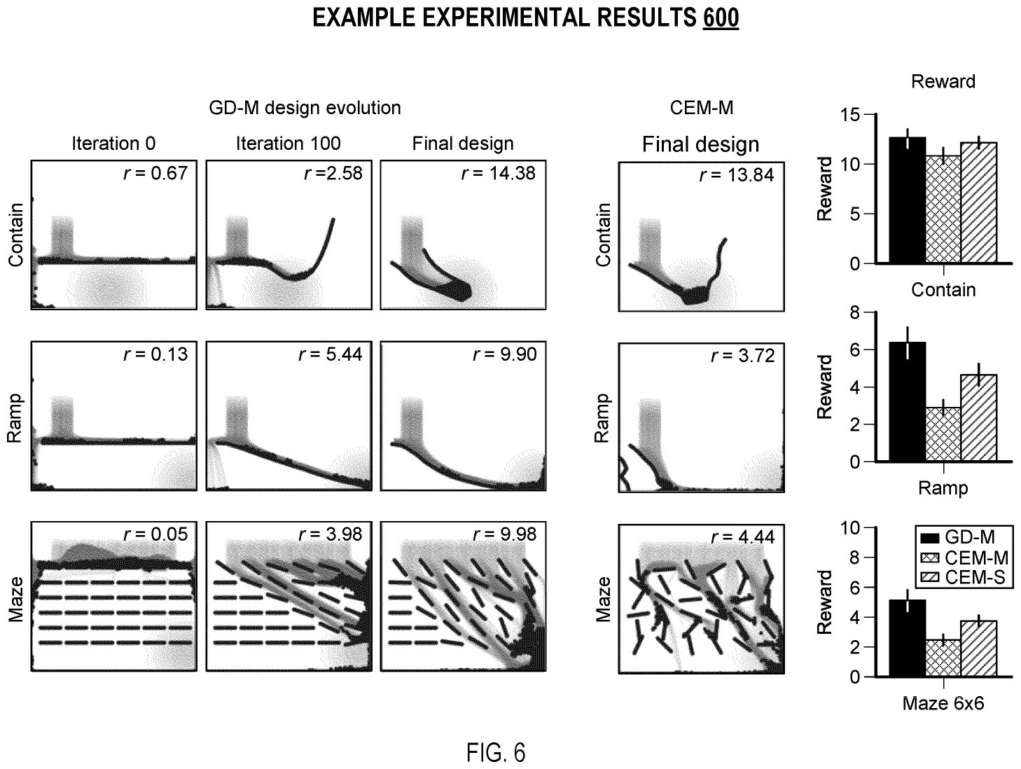

FIG. 6 illustrates another example of experimental results 600 achieved using the design optimization system described in this specification. The results are shown for an environment represented as a collection of particles. The set of design parameters includes 16-36 design parameters. The “r” in FIG. 6 denotes reward for the current design in each panel. The design objective is to create one or more two-dimensional “tool” shapes to direct fluid (represented by particles) into a randomly-sampled reward region. Specifically, FIG. 6 shows three design tasks, where the first task, e.g., “Contain” optimizes design parameters, e.g., joint angles, of a multi-segment tool to catch the fluid by creating cup-or spoon-like shapes. The second task, e.g., “Ramp” optimizes design parameters, e.g., joint angles, of a multi-segment tool to guide the fluid to a distant location. The third task e.g., “Maze” optimizes design parameters, e.g., rotation, of multiple tools to funnel the fluid to the target location.

It can be appreciated that the design optimization system is able to exploit the differentiability of the simulation neural network to directly optimize the quality of a design by iteratively adjusting the values of the design parameters using gradients of a reward for three different tasks. Optimizing the quality of a design using gradients of the reward computed by way of a simulation neural network can enable the optimization system to generate high quality designs for different tasks significantly faster and using fewer computational resources (e.g., memory and computing power) than conventional systems.

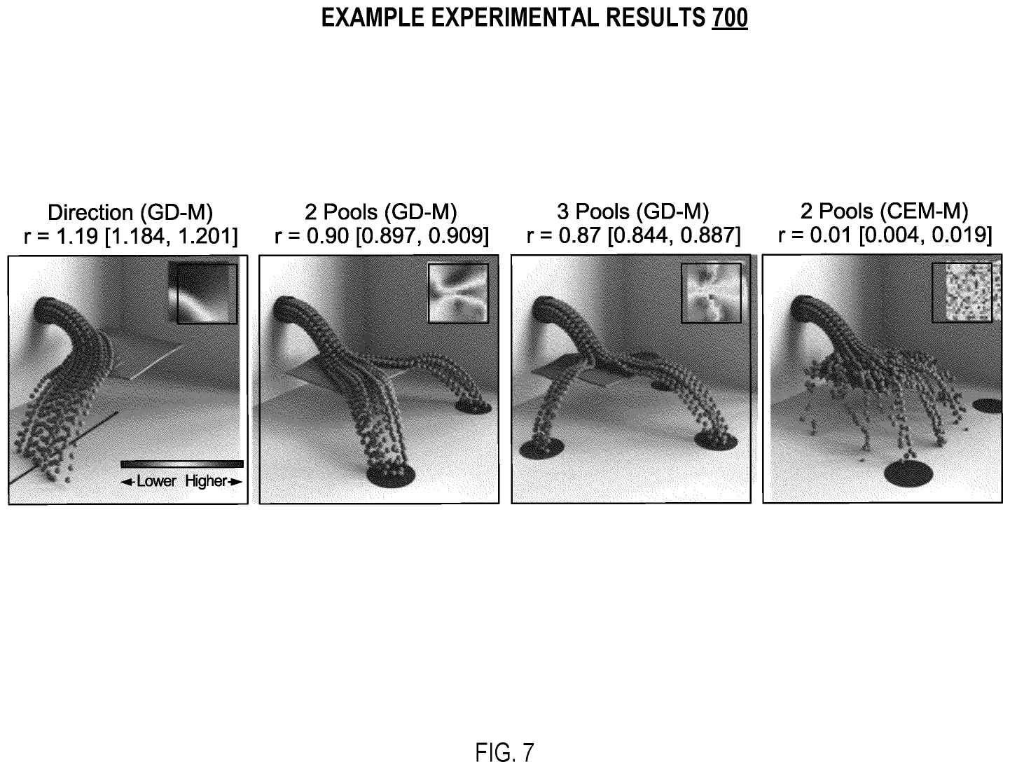

FIG. 7 illustrates another example of experimental results 700 achieved using the design optimization system described in this specification. The results are shown for an environment defined using up to 2000 particles. The set of design parameters includes 625 design parameters. The task includes optimizing a height map of a two-dimensional landscape to direct the fluid towards circular targets. Upper left corner of each panel shows a bird-eye view of the corresponding height map. It can be appreciated that by optimizing the quality of the design by updating the current values of the design parameters using the gradients of a reward in accordance with a gradient descent optimization rule (e.g., “GD-M”) the design optimization system is able to outperform other systems that use alternative techniques (e.g., “CEM-M”).

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework or a Google JAX framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A method performed by one or more computers for optimizing a set of design parameters, the method comprising:
obtaining a respective initial value for each design parameter in the set of design parameters; and
iteratively optimizing current values of the design parameters over a sequence of optimization iterations, comprising, at each optimization iteration:
generating a representation of an initial state of an environment using the current values of the design parameters;
processing an input comprising the representation of the initial state of the environment using a simulation neural network, in accordance with values of a set of simulation neural network parameters, to generate an output that defines a simulation of the state of the environment over a sequence of one or more time steps;
determining a reward based on the simulation of the state of the environment, wherein the reward measures a quality of a design defined by the current values of the design parameters;
determining gradients of the reward with respect to the current values of the design parameters; and
updating the current values of the design parameters using the gradients.

2. The method of claim 1, wherein determining gradients of the reward with respect to the current values of the design parameters comprises:
backpropagating gradients through the set of simulation neural network parameters and into the set of design parameters.

3. The method of claim 1, wherein updating the current values of the design parameters using the gradients comprises:
updating the current values of the design parameters using the gradients in accordance with a gradient descent optimization rule.

4. The method of claim 1, wherein the set of design parameters represent a design of a physical object.

5. The method of claim 4, wherein at each optimization iteration, the environment includes the object having the design represented by the current values of the set of design parameters.

6. The method of claim 4, wherein the object is a wing of an aircraft.

7. The method of claim 4, wherein determining the reward based on the simulation of the state of the environment comprises:
determining one or more aerodynamic features of the object based on the simulation of the state of the environment; and
determining the reward based on the aerodynamic features of the object.

8. The method of claim 1, wherein at each optimization iteration, the representation of the initial state of the environment includes data representing a graph comprising a plurality of nodes.

9. The method of claim 8, wherein each node in the graph represents a particle in the environment or a vertex in a mesh.

10. The method of claim 8, wherein the simulation neural network has a graph neural network architecture.

11. The method of claim 1, wherein generating the output that defines the simulation of the state of the environment over the sequence of one or more time steps comprises, for each time step:
obtaining a representation of the state of the environment at the time step; and
processing the representation of the state of the environment at the time step using the simulation neural network to generate an output that defines a representation of the state of the environment at a next time step.

12. The method of claim 1, wherein the values of the set of simulation neural network parameters are static during the optimization of the set of design parameters.

13. The method of claim 1, further comprising, after a last optimization iteration, outputting the current values of the design parameters.

14. The method of claim 1, wherein the set of design parameters comprises at least 500 design parameters.

15. The method of claim 1, wherein the simulation neural network is one simulation neural network in an ensemble of multiple simulations neural networks, and the method comprises, at each optimization iteration:
for each simulation neural network in the ensemble of simulation neural networks:
processing the input comprising the representation of the initial state of the environment using the simulation neural network to generate an output that defines a respective simulation of the state of the environment over multiple time steps;
determining a respective reward based on the respective simulation of the state of the environment; and
determining respective gradients of the respective reward with respect to the current values of the design parameters; and
updating the current values of the design parameters using the respective gradients determined using each simulation neural network in the ensemble of simulation neural networks.

16. The method of claim 15, wherein each simulation neural network in the ensemble of simulation neural networks has been trained on a different set of training data.

17. The method of claim 15, wherein each simulation neural network in the ensemble of simulation neural networks has a respective set of simulation neural network parameters that are initialized to respective random values prior to being trained.

18. The method of claim 15, wherein updating the current values of the design parameters using the respective gradients determined using each simulation neural network in the ensemble of simulation neural networks comprises:
averaging the gradients determined using each simulation neural network in the ensemble of simulation neural networks; and
updating the current values of the design parameters using the average of the gradients.

19. A system comprising:
one or more computers; and
one or more storage devices communicatively coupled to the one or more computers, wherein the one or more storage devices store instructions that, when executed by the one or more computers, cause the one or more computers to perform operations for optimizing a set of design parameters, the operations comprising:
obtaining a respective initial value for each design parameter in the set of design parameters; and
iteratively optimizing current values of the design parameters over a sequence of optimization iterations, comprising, at each optimization iteration:
generating a representation of an initial state of an environment using the current values of the design parameters;
processing an input comprising the representation of the initial state of the environment using a simulation neural network, in accordance with values of a set of simulation neural network parameters, to generate an output that defines a simulation of the state of the environment over a sequence of one or more time steps;
determining a reward based on the simulation of the state of the environment, wherein the reward measures a quality of a design defined by the current values of the design parameters;
determining gradients of the reward with respect to the current values of the design parameters; and
updating the current values of the design parameters using the gradients.

20. One or more non-transitory computer storage media storing instructions that when executed by one or more computers cause the one or more computers to perform operations for optimizing a set of design parameters, the operations comprising:
obtaining a respective initial value for each design parameter in the set of design parameters; and
iteratively optimizing current values of the design parameters over a sequence of optimization iterations, comprising, at each optimization iteration:
generating a representation of an initial state of an environment using the current values of the design parameters;
processing an input comprising the representation of the initial state of the environment using a simulation neural network, in accordance with values of a set of simulation neural network parameters, to generate an output that defines a simulation of the state of the environment over a sequence of one or more time steps;
determining a reward based on the simulation of the state of the environment, wherein the reward measures a quality of a design defined by the current values of the design parameters;
determining gradients of the reward with respect to the current values of the design parameters; and
updating the current values of the design parameters using the gradients.
